(19) United States
(12) Patent Application Publication
(10) Pub. No.: US 2025/0133683 A1
(43) Pub. Date: Apr. 24, 2025

(54) COMPUTING CHASSIS INCLUDING STORAGE DEVICES AND NETWORK DEVICES

(71) Applicant: Dell Products L.P., Round Rock, TX (US)

(72) Inventors: Kevin Warren Mundt, Livingston, TX (US); Valerie Diane Padilla, Austin, TX (US)

(21) Appl. No.: 18/489,304

(22) Filed: Oct. 18, 2023

(51) Int. Cl. H05K 7/14

(52) U.S. Cl. CPC H05K 7/1492

(57) ABSTRACT

A computing environment, including a computing chassis including bays, the computing chassis including a first side and a second side; a first IOM positioned at the second side of the chassis; a second IOM positioned at the second side of the chassis; a plurality of storage devices, each storage device i) positioned within a respective bay of the bays and ii) coupled to both the first IOM and the second IOM; network devices, each network device positioned within a respective bay of the bays, each network device including network connectors positioned at a first side of the network device and network ports positioned at a second side of the network device opposite to the first side, each network device coupled to both the first IOM and the second IOM by respective network ports of the network device, wherein the network connectors are positioned at the first side of the chassis.

### BACKGROUND

### Field of the Disclosure

The disclosure relates generally to a computing chassis including storage devices and network devices.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Innovative aspects of the subject matter described in this specification may be embodied in a computing environment, including: a computing chassis including a plurality of bays, the computing chassis including a first side and a second side positioned opposite to the first side; a first input/output module (IOM) positioned at the second side of the chassis; a second input/output module (IOM) positioned at the second side of the chassis; a plurality of storage devices, each storage device i) positioned within a respective bay of the plurality of bays and ii) coupled to both the first IOM and the second IOM; and a plurality of network devices, each network device positioned within a respective bay of the plurality of bays, each network device including network connectors positioned at a first side of the network device and network ports positioned at a second side of the network device opposite to the first side, each network device coupled to both the first IOM and the second IOM by respective network ports of the network device, wherein the network connectors are positioned at the first side of the chassis.

Other embodiments of these aspects include corresponding systems and apparatus.

These and other embodiments may each optionally include one or more of the following features. For instance, further including a server coupled to a particular network device of the plurality of network devices. The server is coupled to the particular network device via the network connectors of the particular network device. The server accesses one or more of the plurality of storage devices via the particular network device. Each of the plurality of storage devices include an Ethernet Bunch of Flash (EBOF) storage device. The EBOF storage device includes a non-volatile memory express (NVMe) solid state drive (SSD) and a NVMe to Ethernet converter device. The network connectors of each network device that are positioned at the first side of the chassis include two network connectors. A first connector of the two network connectors is connected to the first IOM and a second connector of the two network connectors is connected to the second IOM. The computing chassis includes 24 bays. A first thickness of each of the network devices is substantially the same as a second thickness of each of the storage devices. The network connectors include RJ-45 and/or SFP connectors. The network connectors of each network device that are positioned at the first side of the chassis include four network connectors. A first connector and a second connector of the four network connectors is connected to the first IOM; and a third and a fourth connector of the four network connectors is connected to the second IOM. The computing chassis includes 40 bays. A first thickness of each of the network devices is greater than a second thickness of each of the storage devices. The first thickness is double the second thickness. The plurality of storage devices are coupled to the first IOM and the second IOM utilizing Ethernet.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of a computing environment including a server chassis.

FIG. 3 illustrates a block diagram of a storage device of the server chassis.

FIG. 4 illustrates a block diagram of a network device of the server chassis.

FIG. 5 illustrates a front view of the server chassis, in a first implementation.

FIG. 6 illustrates a front view of the server chassis, in a first implementation.

### DESCRIPTION OF PARTICULAR EMBODIMENT(S)

This disclosure discusses a computing chassis including storage devices and network devices. In short, the chassis can include storage devices and network devices to provide storage and network connectivity at the chassis, e.g., for edge deployment cases. The network devices bring the connectivity of input/output modules (IOMs) to the front of the chassis.

Specifically, this disclosure discusses a computing environment including a computing chassis including a plurality of bays, the computing chassis including a first side and a second side positioned opposite to the first side; a first input/output module (IOM) positioned at the second side of the chassis; a second input/output module (IOM) positioned at the second side of the chassis; a plurality of storage devices, each storage device i) positioned within a respective bay of the plurality of bays and ii) coupled to both the first IOM and the second IOM; and a plurality of network devices, each network device positioned within a respective bay of the plurality of bays, each network device including network connectors positioned at a first side of the network device and network ports positioned at a second side of the network device opposite to the first side, each network device coupled to both the first IOM and the second IOM by respective network ports of the network device, wherein the network connectors are positioned at the first side of the chassis.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such wires, optical fibers, microwaves, radio waves, and other electromagnetic and/or optical carriers; and/or any combination of the foregoing.

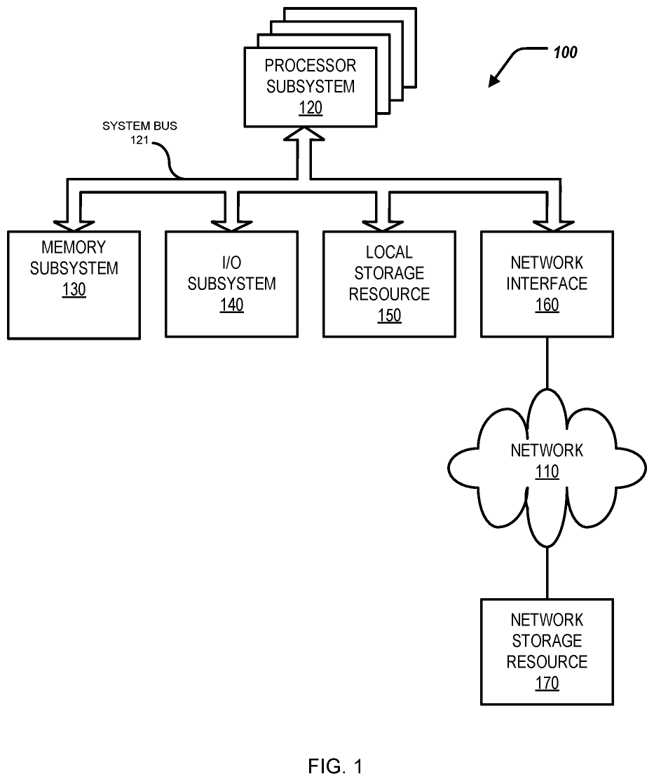

Particular embodiments are best understood by reference to FIGS. 1-6 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include a microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, or a camera, or another type of peripheral device.

Local storage resource 150 may comprise computer-readable media (e.g., hard disk drive, floppy disk drive, CD-ROM, and/or other type of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other type of rotating storage media, flash memory, EEPROM, and/or other type of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g. corporate) network. The network may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g. customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

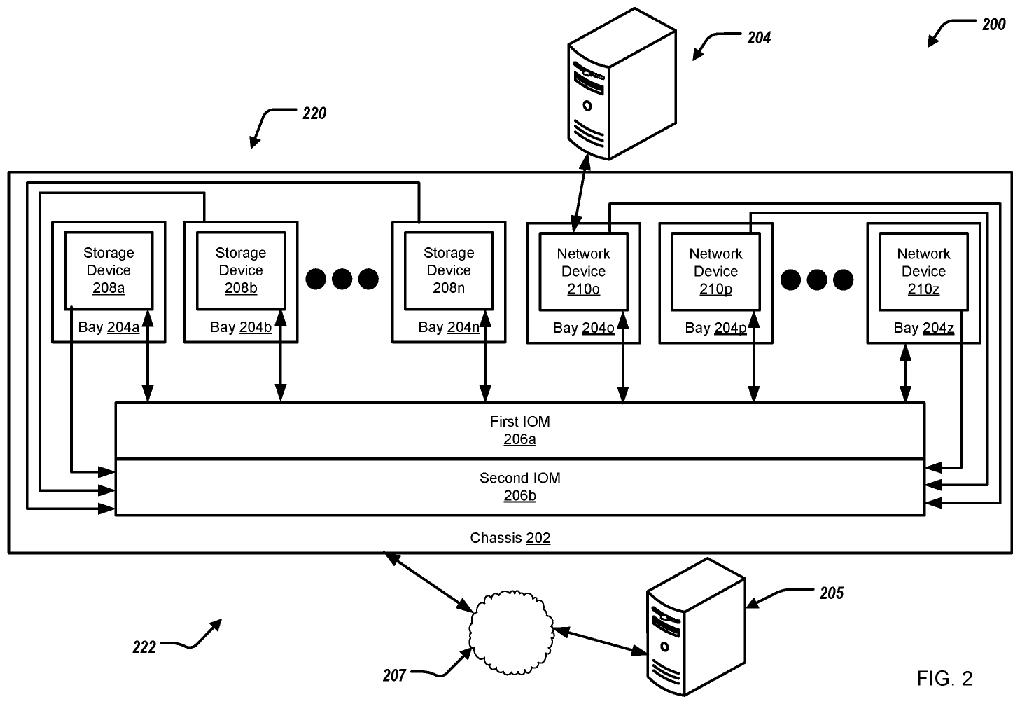

Turning to FIG. 2, FIG. 2 illustrates an environment 200 including a (computing) chassis 202, an information handling system 204 (or server 204), an information handling system 205 (or server 205), and a network 207. The chassis 202 can be a server rack, or part of a server rack. The chassis 202 can include a plurality of bays 204a, 204b, . . . , 204n, 2040, 204p, . . . , 204z (collectively referred to as bays 204). The chassis 202 can include any number of bays 204. The chassis 202 can further include a first input/output module (IOM) 206a and a second input/output module (IOM) 206b (collectively referred to as IOMs 206). The information handling systems 204 and 205 can be similar to the information handling system 100 of FIG. 1. The IOMs 206 can include an Ethernet switch or an Ethernet fabric.

The information handling system 205 can be in communication with the chassis 202 over the network 207. Specifically, the information handling system 205 can be in communication with the IOMs 206 over the network 207.

The chassis 202 can include a plurality of storage devices 208a, 208b, . . . , 208n (collectively referred to as storage devices 208). The storage devices 208 can be positioned within respective bays 204. Specifically, the storage device 208a is positioned within the bay 204a; the storage device 208b is positioned within the bay 204b; and the storage device 208n is positioned within the bay 204n. Any number of storage devices 208 can be positioned within any number of bays 204.

The chassis 202 can include a plurality of network devices 2100, 210p, . . . , 210z (collectively referred to as network devices 210). The network devices 210 can be positioned within respective bays 204. Specifically, the network device 2100 is positioned within the bay 2040; the network device 210p is positioned within the bay 2040; and the network device 210z is positioned within the bay 204z. Any number of storage devices 210 can be positioned within any number of bays 204.

In short, the chassis 202 includes the storage devices 208 and the network devices 210 to provide storage and network connectivity at the chassis 202, e.g., for edge deployment cases. The network devices 210 bring the connectivity of the IOMs 206 to the front of the chassis 202.

The chassis 202 can include a first side 220 and a second side 222. The first side 220 is positioned opposite to the second side 222. The first IOM 206a is positioned at the second side 222 of the chassis 202. That is, the first IOM 206a is coupled to the chassis 202 at the second side 222 of the chassis 202. The second IOM 206b is positioned at the second side 222 of the chassis 202. That is, the second IOM 206b is coupled to the chassis 202 at the second side 222 of the chassis 202. In some examples, the IOMs 206 and the bays 204 are both positioned along the same side (e.g., the first side 220 or the second side 222).

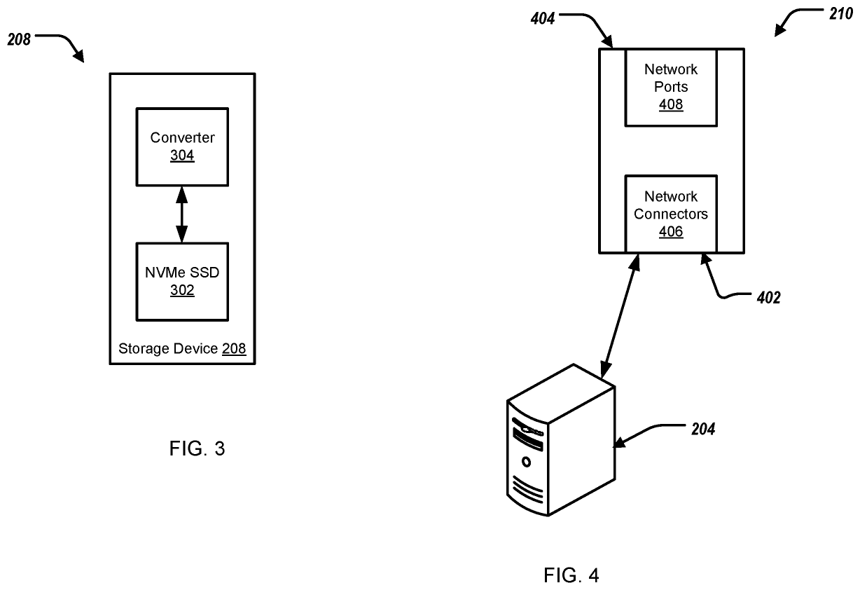

The storage devices 208 are coupled to, or connected to, the IOMs 206. For example, each of the storage devise 208 can include an Ethernet Bunch of Flash (EBoF) storage device. FIG. 3 illustrates a block diagram of the storage device 208. The storage device 208 can include a non-volatile memory express (NVMe) solid state drive (SSD) 302 and a NVMe to Ethernet converter device 304. The storage devices 208 are coupled to (or connected to) to the first IOM 206a and the second IOM 206b utilizing (or over) Ethernet.

The network devices 210 are coupled to, or connected to, the IOMs 206. FIG. 4 illustrates a block diagram of the network device 210. The network device 210 can include a first side 402 and a second side 404 opposite to the first side 402. The network device 210 can include network connectors 406 positioned at the first side 402. The network device 210 can include network ports 408 positioned at the second side 404. The network device 210 is coupled to the IOMs 206 via the network ports 408. The network connectors 406 can be positioned along the first side 220 of the chassis 202. In some examples, the network connectors 406 are registered jack (RJ) 45 connectors. In some examples, the network connectors 406 are small form-factor pluggable (SFP) connectors.

As a result of the network devices 210 and the storage devices 208 connected to the IOMs 206, any of the network devices 210 are connected to (coupled with) any of the storage devices 208. That is, any of the network devices 210 can provide access to any of the storage devices 208.

In some examples, the server 204 is coupled to (in communication with) the network device 210a. Specifically, the server 204 is coupled to the network device 210a via the network connectors 406 of the network device 210a. The server 204 can access any of the storage devices 208 via the network device 2100. That is, the server 204 can access any of the storage devices 208 through the network device 2100, and the IOMs 206.

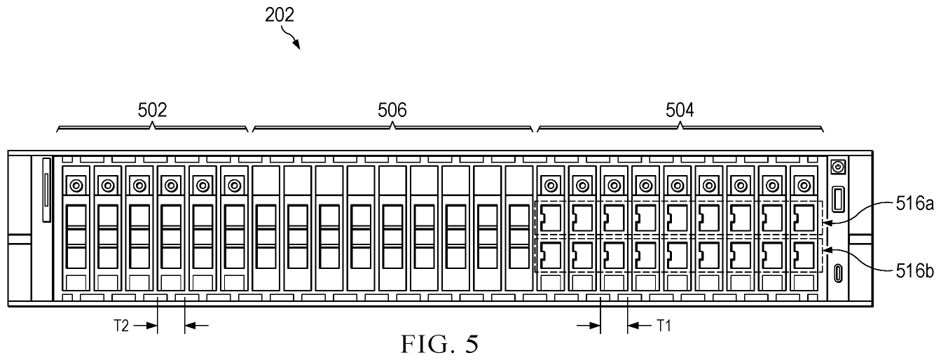

FIG. 5 illustrates a front view of the chassis 202, in a first implementation, and in particular, the first side 220 of the chassis 202. In some examples, the computing chassis 202 includes 24 bays 204. In the illustrated example, the chassis 202 includes 6 storage devices 208 positioned within respective bays 204, indicated by grouping 502; however, the chassis 202 can include any number of storage devices 208. In the illustrated example, the chassis 202 includes 9 network devices 210 positioned within respective bays 204, indicated by grouping 504; however, the chassis 202 can include any number of network devices 210. In the illustrated example, the chassis includes 9 empty bays 204, indicated by the grouping 506; however, the chassis 202 can include any number of empty bays 204. In some examples, the storage devices 208 include a 2.5 inches form factor.

In some examples, each of the network devices 210 include two network connectors 406, shown as first network connectors 516a and second network connectors 516b. In some examples, the first network connectors 516a of each of the network devices 210 is connected to the first IOM 206a. In some examples, the second network connectors 516b of each of the network devices 210 is connected to the second IOM 206b.

Each of the network devices 210 have a first thickness T1. Each of the storage devices 208 have a second thickness T2. In some examples, the first thickness T1 of each of the network devices 210 is substantially the same as the second thickness T2 of each of the storage devices 208.

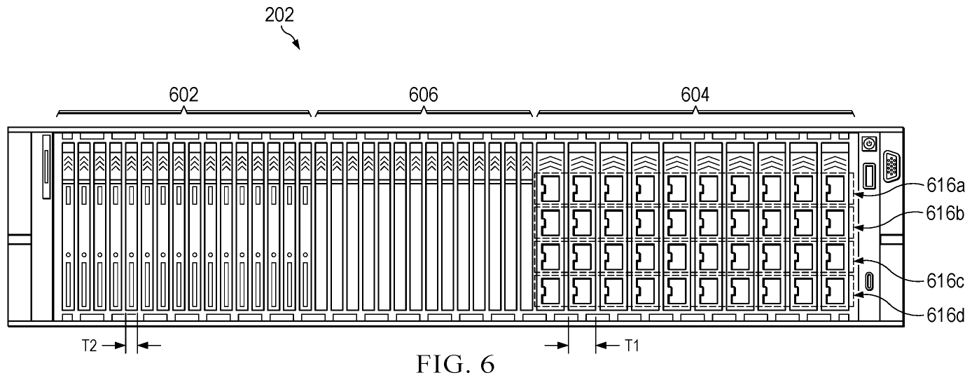

FIG. 6 illustrates a front view of the chassis 202, in a first implementation, and in particular the first side 220 of the chassis 202. In some examples, the computing chassis 202 includes 40 bays 204. In the illustrated example, the chassis 202 includes 16 storage devices 208 positioned within respective bays 204, indicated by grouping 602; however, the chassis 202 can include any number of storage devices 208. In the illustrated example, the chassis 202 includes 10 network devices 210 positioned within respective bays 204, indicated by grouping 604; however, the chassis 202 can include any number of network devices 210. In the illustrated example, the chassis includes 14 empty bays 204, indicated by the grouping 606; however, the chassis 202 can include any number of empty bays 204. In some examples, the storage devices 208 include an enterprise and data center standard form factor (EDSFF) E3 thin form factor.

In some examples, one or more of the network devices 210 are positioned within two bays 204.

In some examples, each of the network devices 210 include four network connectors 406, shown as first network connectors 616a, second network connectors 616b, third network connectors 616c, and fourth network connectors 616d. In some examples, the first network connectors 616a and the second network connectors 616b of each of the network devices are connected to the first IOM 206a. In some examples, the third network connectors 616c and the fourth network connectors 616d of each of the network devices 210 are connected to the second IOM 206b.

Each of the network devices 210 have a first thickness T1. Each of the storage devices 208 have a second thickness T2. In some examples, the first thickness T1 of each of the network devices 210 is greater than the second thickness T2 of each of the storage devices 208. In some examples, the first thickness T1 is double the second thickness T2.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated other-wise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A computing environment, including:
a computing chassis including a plurality of bays, the computing chassis including a first side and a second side positioned opposite to the first side;
a first input/output module (IOM) positioned at the second side of the chassis;
a second input/output module (IOM) positioned at the second side of the chassis;
a plurality of storage devices, each storage device i) positioned within a respective bay of the plurality of bays and ii) coupled to both the first IOM and the second IOM; and
a plurality of network devices, each network device positioned within a respective bay of the plurality of bays, each network device including network connectors positioned at a first side of the network device and network ports positioned at a second side of the network device opposite to the first side, each network device coupled to both the first IOM and the second IOM by respective network ports of the network device, wherein the network connectors are positioned at the first side of the chassis.

2. The computing environment of claim 1, further including a server coupled to a particular network device of the plurality of network devices.

3. The computing environment of claim 2, wherein the server is coupled to the particular network device via the network connectors of the particular network device.

4. The computing environment of claim 3, wherein the server accesses one or more of the plurality of storage devices via the particular network device.

5. The computing environment of claim 1, wherein each of the plurality of storage devices include an Ethernet Bunch of Flash (EBoF) storage device.

6. The computing environment of claim 5, wherein the EBOF storage device includes a non-volatile memory express (NVMe) solid state drive (SSD) and a NVMe to Ethernet converter device.

7. The computing environment of claim 1, wherein the network connectors of each network device that are positioned at the first side of the chassis include two network connectors.

8. The computing environment of claim 7, wherein a first connector of the two network connectors is connected to the first IOM and a second connector of the two network connectors is connected to the second IOM.

9. The computing environment of claim 8, wherein the computing chassis includes 24 bays.

10. The computing environment of claim 9, wherein a first thickness of each of the network devices is substantially the same as a second thickness of each of the storage devices.

11. The computing environment of claim 1, wherein the network connectors include RJ-45 and/or SFP connectors.

12. The computing environment of claim 1, wherein the network connectors of each network device that are positioned at the first side of the chassis include four network connectors.

13. The computing environment of claim 12, wherein a first connector and a second connector of the four network connectors is connected to the first IOM; and a third and a fourth connector of the four network connectors is connected to the second IOM.

14. The computing environment of claim 13, wherein the computing chassis includes 40 bays.

15. The computing environment of claim 14, wherein a first thickness of each of the network devices is greater than a second thickness of each of the storage devices.

16. The computing environment of claim 15, wherein the first thickness is double the second thickness.

17. The computing environment of claim 1, wherein the plurality of storage devices are coupled to the first IOM and the second IOM utilizing Ethernet.
